(19) United States
(12) Patent Application Publication
(10) Pub. No.: US 2023/0391347 A1
(43) Pub. Date: Dec. 7, 2023

(54) DEVICE AND METHOD FOR DETECTING SHORT-CIRCUIT BETWEEN SUB-SYSTEMS IN DISTRIBUTION SYSTEM, AND DISTRIBUTION SYSTEM INCLUDING THE SAME

(71) Applicant: HL MANDO CORPORATION, Gyeonggi-do (KR)

(72) Inventor: DaeHun HWANG, Gyeonggi-do (KR)

(21) Appl. No.: 18/097,193

(22) Filed: Jan. 13, 2023

(30) Foreign Application Priority Data
Jun. 7, 2022 (KR) 10-2022-0068710

(51) Int. Cl. B60W 50/02; G01R 31/52; G01R 31/00

(52) U.S. Cl. CPC B60W 50/0205; G01R 31/52; G01R 31/006; B60W 2050/0215; B60W 2510/202; B60W 10/20

(57) ABSTRACT

A device and method for detecting short-circuit between sub-systems in a distribution system, and a distribution system including the same are disclosed. A device for detecting short-circuit may include a first sensor, a first electronic control unit (ECU) electrically connected to the first sensor, and a first signal line connecting the first sensor and the first ECU. The first ECU may perform initialization for initial configuration setting when receiving a first sensor signal through the first signal line, and may perform, when executing a specific periodic function, a short-circuit detection with a second sub-system, which is another sub-system included in the distribution system, by comparing a difference value between a current system timer value when receiving a current sensor signal and a previous system timer value when receiving a previous sensor signal with a threshold value or range.

### CROSS REFERENCE TO RELATED APPLICATION

This application claims priority from Korean Patent Application No. 10-2022-0068710, filed on Jun. 7, 2022, which is hereby incorporated by reference for all purposes as if fully set forth herein.

### TECHNICAL FIELD

Various embodiments of the present disclosure generally relate to a device and method for detecting short-circuit between sub-systems in a distribution system, and a distribution system including the same. More particularly, some embodiments of the present disclosure relate to a device and method for detecting a short-circuit occurring between signal lines connecting between each sub-system and a corresponding sensor in a distribution system including two or more sub-systems related to vehicle control.

### BACKGROUND

Recently, consumers have a lot of interest in the performance and safety of vehicles. As the demand for vehicle performance, driver convenience, and safety increases, there is continuously in progress the research and development of advanced driver assistance systems (ADAS) for assisting a driver or a vehicle operator in driving the vehicle by controlling the vehicle. Here, the ADAS may allow the driver to take appropriate actions based on external environmental information detected by vehicle sensors and cameras, or may automatically control the vehicle, thereby minimizing or blocking damage caused by vehicle accidents by establishing a safer driving environment.

In general, there may be provided a control system for various detections and actuator control related to vehicle control in the vehicle. Examples of the control system may include an automatic steering system and an automatic braking system for steering or braking control during autonomous driving or semi-autonomous driving. As another example, the control system may include a driver assistance system (DAS) for controlling a vehicle behavior in specific conditions, such as a lane keeping assist system (LKAS), an automatic emergency braking (AEB) system, and the like.

Since such a control system is important for driving stability of a vehicle, standards such as ISO 26262 define specific requirements for functional safety for these vehicle control systems.

In order to ensure stability above a certain level even when a failure occurs in a vehicle control system performing a specific function, there may be required to duplicate or multiplex one vehicle control system. As an example, a vehicle control system of a specific function may be configured with two or more sub-systems, and when an error or a failure occurs in one sub-system, the remaining sub-systems may operate.

Such a duplicate/multiplex control system may be referred as a redundancy system, a distribution system, or the like.

Meanwhile, in this distribution system, a short-circuit may occur in a signal line in each sub-system. In addition, since two or more sub-systems in the distribution system are disposed/implemented immediately adjacent to each other, a short-circuit may also occur between signal lines of the sub-systems.

In addition, even if a short-circuit of a signal line between sub-systems occurs in a distribution system, since the reference between the sub-systems is different, in some cases, there may occur a problem of recognizing an erroneous signal with a short-circuit as a normal signal.

Therefore, if an incorrect (or erroneous) sensor signal is recognized as a normal sensor signal due to a short-circuit between sub-systems in the distribution system, there may occur an error in the vehicle control function by the distribution system, and accordingly, there may be not guaranteed the driving stability of the vehicle.

Therefore, it is necessary to accurately detect a short-circuit of a signal line between sub-systems in a distribution system applied to a vehicle.

### SUMMARY

In order to solve the above problems, embodiments of the present disclosure may provide a device and method for detecting a short-circuit of a signal line between sub-systems in a distribution system including two or more sub-systems with the same function.

Some embodiments of the present disclosure may provide a device and method for detecting a short-circuit of a signal line connecting between sub-systems in a distribution system applied to a vehicle.

Certain embodiments of the present disclosure may provide a device and method for detecting a short-circuit between a first sensor signal line connecting between a first ECU and a first sensor included in a first sub-system and a second sensor signal line connecting between a second ECU and a second sensor included in a second sub-system in a distribution system including multiple sub-systems.

In an aspect of the present disclosure, there may provide a device for detecting a short-circuit of a first sub-system in a distribution system including two or more sub-systems performing the same function for vehicle control including a first sensor, a first electronic control unit (ECU) electrically connected to the first sensor, and a first signal line connecting the first sensor and the first ECU, wherein the first ECU is configured to perform initialization for initial configuration setting when a first sensor signal is received through the first signal line, and to perform, when executing a specific periodic function, a short-circuit detection with a second sub-system, which is another sub-system included in the distribution system, by comparing a difference value between a current system timer value when receiving a current sensor signal and a previous system timer value when receiving a previous sensor signal with a threshold value.

In another aspect of the present disclosure, there may provide a distribution system including a first sub-system including a first ECU, a first sensor, and a first sensor signal line connecting the first ECU and the first sensor, and configured to perform a first function related to vehicle control, and a second sub-system including a second ECU, a second sensor, and a second sensor signal line connecting the second ECU and the second sensor, and configured to perform the first function in conjunction with the first sub-system. In this case, the first ECU may be configured to compare, when executing a specific periodic function, a difference value between a current system timer value when receiving a current sensor signal through the first sensor signal line and a previous system timer value when receiving a previous sensor signal through the first sensor signal line with a threshold value, and to perform a short-circuit determination between the first sensor signal line and the second sensor signal line based on the comparison result.

In another aspect of the present disclosure, there may provide a method for detecting short-circuit between sub-systems in distribution system including a first sub-system for performing a first function related to vehicle control and a second sub-system for performing the first function in conjunction with the first sub-system including performing, by the first sub-system, initialization for initial configuration setting when a first sensor signal is received from a first sensor through a first sensor signal line connected to the first sensor, comparing, by the first sub-system, when executing a specific periodic function, a difference value between a current system timer value when receiving a current sensor signal from the first sensor and a previous system timer value when receiving a previous sensor signal from the first sensor with a threshold value, and performing, by the first sub-system, a determination of a short-circuit of a signal line between the first sub-system and the second sub-system.

According to some embodiments of the present disclosure, a short-circuit in a signal (line) between sub-systems comprised in a distribution system including two or more sub-systems with the same function can be detected.

In addition, according to certain embodiments of the present disclosure, it is possible to detect a short-circuit between a first sensor signal line connecting between a first ECU and a first sensor included in a first sub-system and a second sensor signal line connecting between a second ECU and a second sensor included in a second sub-system.

Accordingly, by detecting a short-circuit between a plurality of sub-systems in a distribution system for a vehicle, it is possible to secure a stable operation of the distribution system, and to satisfy a functional safety requirement required for a vehicle.

### BRIEF DESCRIPTION OF THE DRAWINGS

FIG. 1 illustrates an in-vehicle distribution system according to an embodiment of the present disclosure.

FIG. 2 illustrates examples of sensor signals in the case that a short-circuit occurs between two sub-systems in the distribution system of FIG. 1.

FIG. 3 is a schematic configuration diagram of a vehicle distribution system according to an embodiment of the present disclosure.

FIG. 4 is a detailed configuration diagram of a distribution system for a vehicle and first and second sub-systems included therein according to an embodiment of the present disclosure.

FIG. 5 is a flowchart of a method for detecting a short-circuit in a distribution system for a vehicle according to an embodiment of the present disclosure.

FIG. 6 is a flowchart of an initialization process of a short-circuit detection method according to an embodiment of the present disclosure.

FIG. 7 is a flowchart for detecting a short-circuit in a method for detecting a short-circuit according to an exemplary embodiment of the present disclosure.

FIG. 8 is a block diagram of a steer-by-wire steering system to which a distribution system capable of detecting a short-circuit according to an embodiment of the present disclosure.

FIG. 9 illustrates an example of information stored in an ECU storage in a device for detecting short-circuit according to an embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, an embodiment will be described in detail with reference to the drawings.

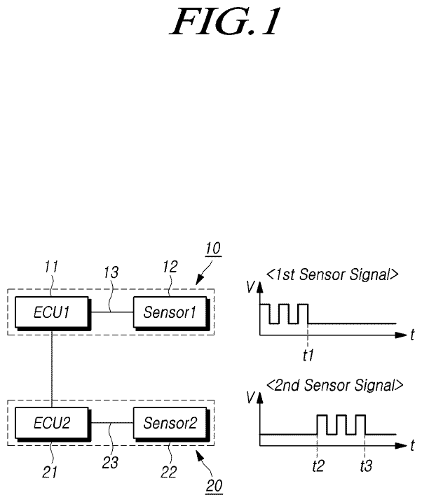

FIG. 1 illustrates an example of an in-vehicle distribution system to which an embodiment of the present disclosure may be applied. In particular, FIG. 1 illustrates examples of sensor signals in a normal state in an in-vehicle distribution system to which an embodiment of the present disclosure can be applied.

Referring to FIG. 1, a distribution system for vehicle control to which an embodiment of the present disclosure can be applied may include a first sub-system 10 and a second sub-system 20 which perform a specific control function related to a vehicle.

The first sub-system 10 and the second sub-system 20 may be redundant control devices for performing the same vehicle control function. The first sub-system 10 may include a first electronic control unit (ECU) 11 (ECU1), a first sensor 12 (Sensor 1), and a first sensor signal line 13 connecting the first ECU 11 and the first sensor 12. Similarly, the second sub-system 20 may include a second ECU 21 (ECU2), a second sensor 22 (Sensor2), and a second sensor signal line 23 connecting the second ECU and the second sensor.

The first ECU 11 and the second ECU 21 may be connected through an ECU signal line, and at least one of the first ECU 11 and the second ECU 21 performs vehicle control function. As described above, the first ECU 11 and the second ECU 21 can be configured to perform the same function of controlling the vehicle as each other.

If the distribution system as shown in FIG. 1 operates normally, the first sensor 12 and the second sensor 22 generate a first sensor signal and a second sensor signal, respectively, to transmit them to the first ECU 11 and the second ECU 21, respectively.

In this case, the first sub-system 10 and the second sub-system 20 may be in an asynchronous state.

Accordingly, the first sensor signal and the second sensor signal each may have pulses at different times. That is, as shown on the right side of FIG. 1, the first sensor signal may be a pulse signal during 0 to t1, and the second sensor signal may be a pulse signal during t2 to t3. That is, the first sensor signal is a pulse signal for the first duration t1, and has a low value (e.g. a lower voltage level) for the remaining time after t1. the second sensor signal is a pulse signal for the second duration t3-t2, and has a low value (e.g. a lower voltage level) during 0 to t2 and after t3.

In the normal state shown in FIG. 1, the first sensor signal may be input to the first ECU 11 and the second sensor signal may be input to the second ECU 21 to be used normally.

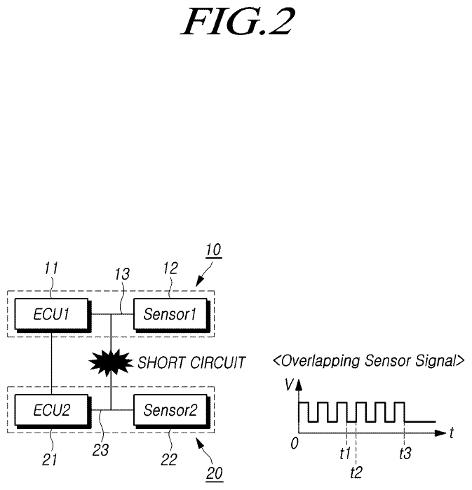

FIG. 2 illustrates an example of a sensor signal in the case that a short-circuit occurs between two sub-systems in the distribution system for vehicle control of FIG. 1.

As shown in FIG. 2, since the first and second sub-systems 10 and 20 can be positioned very close to each other, the short-circuit may occur between the first and second sub-systems 10 and 20.

Specifically, there may occur the short-circuit between the first sensor signal line 13 connecting the first ECU 11 and the first sensor 12 and the second sensor signal line 23 connecting the second ECU 21 and the second sensor 22.

If the short-circuit between the first sensor signal line 13 and the second sensor signal line 23 occurs, the first sensor signal and the second sensor signal may overlap each other to have an overlapping sensor signal pattern.

As shown in FIG. 2, the overlapping sensor signal may include a pulse during a time period between 0 and t1, which is the first sensor signal, and a pulse during a time period between t2 and t3 which is the second sensor signal, and this overlapping sensor signal may be applied or input to the first ECU 11 and the second ECU 21.

In this case, the first ECU 11 and the second ECU 21 may determine that there is abnormality in the sensor signal (overlapping sensor signal), received from the first sensor 12 and the second sensor 22, by analyzing the pulse pattern of the overlapping sensor signal.

For example, if the first sensor signal and the second sensor signal have the same pulse width and pulse period as each other, abnormality of the sensor signal may be detected by checking the non-uniformity of the pulse period of the pulses included in the overlapping sensor signal.

However, if the first sensor signal and the second sensor signal have different pulse widths or are different pulse width modulation (PWM) signals from each other, there may be difficult in determining the abnormality of the overlapping sensor signal.

In this case, the first ECU 11 and the second ECU 21 may recognize the abnormal overlapping sensor signal as the normal first and second sensor signal, and perform control based thereon. Accordingly, the first ECU 11 and the second ECU 21 may not be able to perform normal control, thereby causing a risk to vehicle stability.

Accordingly, in an embodiment of the present disclosure, there may provide, in a distributed vehicle system including two or more sub-systems which are capable of performing the same function, a method for detecting a short-circuit of a signal (line) between sub-systems.

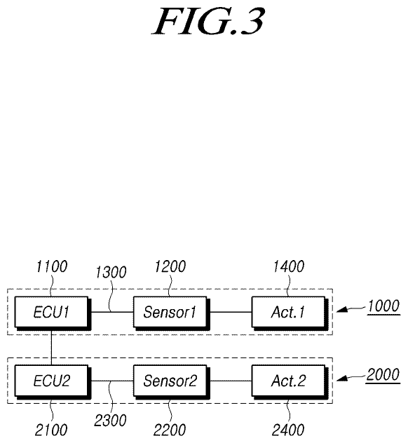

FIG. 3 is a schematic configuration diagram of a vehicle distribution system according to an embodiment of the present disclosure.

Referring to FIG. 3, the distribution system for a vehicle according to an embodiment may include a first sub-system 1000 and a second sub-system 2000 that commonly perform a first function related to vehicle control. The first sub-system 1000 and the second sub-system 2000 may be connected to each other, and one of the first and second sub-systems 1000 and 2000 may operate as a master controller and the other of the first and second sub-systems 1000 and 2000 may operate as a slave controller, but is not limited thereto.

For example, if an error or an abnormality occurs in the first sub-system 1000 while the first sub-system 1000 performs a first function as the main controller, the second sub-system 2000 may take over the control associated with a vehicle immediately and continuously perform the first function which has been performed by the first sub-system 1000.

The first sub-system 1000 may include a first ECU 1100, a first sensor 1200 and a first sensor signal line 1300 connecting the first ECU 1100 and the first sensor 1200, and may perform a first function related to vehicle control. Also, the first sub-system 1000 may further include a first actuator 1400 (Act. 1) operating under the control of the first ECU 1100.

Similarly, the second sub-system 2000 may include a second ECU 2100, a second sensor 2200 and a second sensor signal line 2300 connecting the second ECU 2100 and the second sensor 2200, and may perform the first function related to vehicle control by interworking with the first sub-system 1000. Also, the second sub-system 2000 may further include a second actuator 2400 (Act. 2) operating under the control of the second ECU 2100.

The distribution system in the present disclosure may be expressed in other terms such as a redundancy system or a fail-safe system or a redundancy/multiplex system.

The first function related to vehicle control performed by the distribution system of an embodiment of the present disclosure may include various control functions included in, for example, but not limited to, a driver assistance system (DAS), and an automatic steering system, an automatic braking system required for autonomous or semi-autonomous driving.

Among various systems listed above, compared to the DAS function, an automatic steering system, an automatic braking system for the autonomous or semi-autonomous driving may be more important for functional safety of a vehicle. Accordingly, the distribution system according to the present disclosure may perform the first function for automatic steering and/or automatic braking required for autonomous or semi-autonomous driving.

In addition to the function of performing the first function, the first ECU 1100 included in the first sub-system 1000 may perform a short-circuit detection function for detecting a short-circuit with the second sub-system 2000 according to the present embodiment.

Accordingly, the first ECU 1100 performing the short-circuit detection function according to the present embodiment may be defined or referred as a short-circuit detection device.

In addition, since the distribution system according to the present embodiment is a redundant system, the second ECU 2100 included in the second sub-system 2000 may also perform the short-circuit detection function for detecting a short-circuit with the first sub-system in addition to the first function, and the second ECU 2100 may be also defined or referred as a short-circuit detection device according to the present embodiment.

When executing a specific periodic function for performing the above-described first function related to vehicle control, the first ECU 1100 as a short-circuit detection device may compare a difference value between a current system timer value when receiving a current sensor signal through the first sensor signal line 1300 and a previous system timer value when receiving a previous sensor signal through the first sensor signal line 1300 with a threshold value, and may perform a determination of whether short-circuit between the first sensor signal line 1300 and the second sensor signal line 2300 occurs based on the comparison result.

In the present disclosure, short-circuit between the first sub-system 1000 and the second sub-system 2000 may include occurrence of short-circuit between the first sensor signal line and the second sensor signal line, but is not limited thereto.

In addition, the first ECU 1100 as a short-circuit detection device may further perform an initialization for initial configuration setting when the first sensor signal is received from the first sensor 1200 through the first signal line 1300.

The initialization may be a configuration for setting various parameters necessary for the first ECU 1100 to perform a short-circuit detection function. In this case, the initialization parameters used for the initial configuration setting may include at least one of 1) a first system timer value or storage location thereof (e.g., the register address of the system timer) when receiving the first sensor signal, 2) setting information of a transmission period of a sensor trigger signal transmitted by the first ECU 1100 to the first sensor 1200, 3) processing priority information of an interrupt router (IR) module included in the first ECU 1100, 4) storage target information to be stored in an ECU storage (ECU memory) through a direct memory access (DMA) module included in the first ECU 1100, and 5) storage location information in the ECU memory for storing the storage target information.

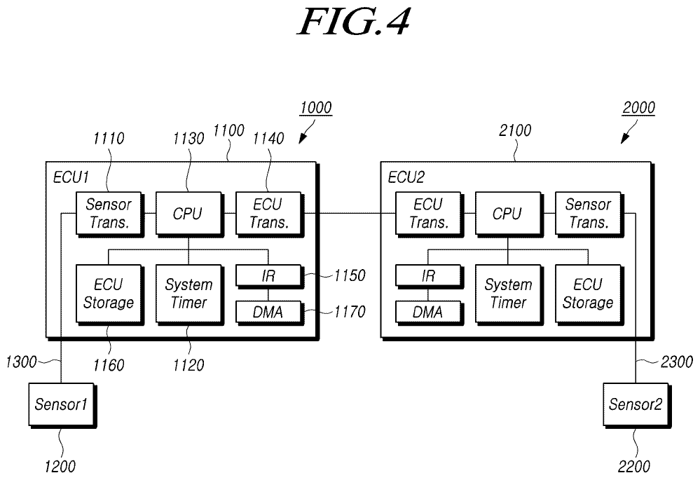

This initialization configuration will be described in more detail with reference to FIG. 4 below.

Meanwhile, the first ECU 1100 as a short-circuit detection device may generate a sensor trigger signal at specific period and transmit it to the first sensor 1200, and the first sensor 1200 may generate sensing data in response to the reception of the sensor trigger signal and transmit the sensing data to the first ECU 1100.

The transmission period of the sensor trigger signal may have the same meaning as a transmission/reception period of a sensor signal including the sensing data.

The threshold value for short-circuit detection may be the transmission period of the sensor trigger signal or the transmission/reception period of the sensor signal of the first sensor. Alternatively, the threshold value may be set by adding or subtracting a certain margin value as an error range to the transmission period of the sensor trigger signal or the transmission/reception period of the sensor signal of the first sensor.

In addition, an execution period of the periodic function of the first ECU 1100 as a short-circuit detection device may be an integer multiple of the transmission/reception period of the sensor signal of the first sensor 1200 or the transmission period of the sensor trigger signal.

For example, the execution period of the periodic function for performing the first function related to vehicle control may be 1 ms, and the transmission/reception period of the sensor signal or the transmission period of the sensor trigger signal may be 200 um or 125 um.

If the execution period of the periodic function is 1 ms and the transmission/reception period of the sensor signal or the transmission period of the sensor trigger signal is 200 um, five sensor signal transmissions/receptions are performed during the execution period of the periodic function. Accordingly, four short-circuit detection functions may be performed during one execution period of the periodic function. That is, during one execution period of the periodic function, the difference value between the current system timer value and the previous system timer value can be calculated as a total of four times, and a short-circuit can be detected by comparing one or more of the four difference values with a threshold value.

In this case, if the difference value between the current system timer value and the previous system timer value is not substantially the same as the threshold value, there may be determined that short-circuit between the first sub-system 1000 and the second sub-system 2000 has occurred.

In addition, the distribution system according to the present embodiment may be for a steer-by-wire steering device for automatic steering control during autonomous driving. In this case, the first sensor 1200 and the second sensor 2200 may be a steering torque sensor or a motor position sensor of a steering motor.

As described above, by using the distribution system for automatic steering control, which is important for vehicle driving safety, according to the present embodiment, the functional stability requirements of the vehicle specified in ISO 26262 or the like may be satisfied.

In addition, the first ECU 1100 as a short-circuit detection device may be further configured to perform, in addition to the first short-circuit detection performed based on the interval of the system timer value, one or more of a second short-circuit detection by checking a protocol error between the first sensor 1200 and the first ECU 1100, a third short-circuit detection by checking a reception error in which the first ECU 1100 cannot receive a sensor signal from the first sensor 1200, and a fourth short-circuit detection through analysis of reception signal pattern.

The first ECU 1100 and the second ECU 1200 as short-circuit detection devices may be hardware or software components, and may include a sensor transceiver, a system timer, a central processing unit (CPU), an ECU transceiver, and the like. In addition, the first ECU 1100 and the second ECU 1200 may further include an interrupt router (IR) module, an ECU storage (or ECU memory), and a direct memory access (DMA) module for managing the storage in order to transmit and receive the sensor signal and store the system timer value.

The detailed configuration of the first ECU 1100 and the second ECU 1200 as short-circuit detection devices will be described in more detail below with reference to FIG. 4.

FIG. 4 is a detailed configuration diagram of schematically showing a distribution system for a vehicle including first and second sub-systems according to an embodiment of the present disclosure.

Referring to FIG. 4, the first sub-system 1000 as a short-circuit detection device included in the distribution system for a vehicle according to the present embodiment may include a first sensor 1200 for generating and outputting a sensor signal including sensing data, a first ECU 1100 electrically connected to the first sensor 1200 to perform a first function related to vehicle control, and a first (sensor) signal line 1300 connecting the first sensor 1200 and the first ECU 1100.

That is, in the present disclosure, each sub-system included in the distribution system or each electronic control unit (ECU) included therein may be defined or referred as a short-circuit detection device.

In this case, the first ECU 1100 may perform an initialization function for initial configuration setting when the first sensor signal is received through the first signal line 1300.

In addition, when executing a specific periodic function for performing the first function related to vehicle control, the first ECU 1100 may compare a difference value between a current system timer value when receiving a current sensor signal and a previous system timer value when receiving a previous sensor signal with a threshold value, thereby performing the detection of a short-circuit with the second sub-system, which is another sub-system included in the distribution system.

Referring to FIG. 4, for such an initialization function and a short-circuit detection function, the first ECU 1100 may include a sensor transceiver 1110, a system timer 1120, a central processing unit (CPU) 1130, an ECU transceiver 1140, and the like. In addition, the first ECU 1100 may further include an interrupt router (IR) module 1150, ECU storage 1160, and direct memory access (DMA) module 1170 for managing the storage in order to transmit and receive sensor signals and store system timer values.

The configurations of the first ECU 1100 may be implemented as a certain hardware module or software module included in a vehicle control chip.

The sensor transceiver 1110 may perform signal transmission and reception with the first sensor 1200. Specifically, the first ECU 1100 periodically generates a sensor trigger signal and transmits it to the first sensor 1200 through the sensor transceiver 1110. The first sensor 1200 transmits a sensor signal including sensing data to the first ECU 1100 in response to receiving a sensor trigger signal.

The sensor trigger signal may be an SPC trigger pulse signal including a short pulse width modulation code (SPC). The sensing data may be generated based on a SENT(Single Edge Nibble Transmission) protocol used by a SENT module supported by the first ECU 1100, and may include a SENT frame.

Specifically, communication between the first sensor 1200 and the first ECU 1100 may be performed based on, for example, but not limited to, a SAE J2716 SENT (Single Edge Nibble Transmission) protocol.

The system timer 1120 may generate and output a system timer value at the time of receiving a sensor signal when the sensor signal is received.

The central processing unit (CPU) 1130 may be responsible for overall control of components comprised in or associated with the first ECU 1100.

The ECU transceiver 1140 may transmit or receive signals to and from ECU(s) of other sub-system(s) included in the distribution system. In this case, the transmission signal may include, but not limited to, status information indicating an abnormal state of each ECU, information indicating a main or slave of each ECU, and information on a control right or priority of the distribution system.

The interrupt router (IR) module 1150 may perform a function of generating an interrupt for receiving the sensor signal.

The ECU storage or the ECU memory 1160 may be a memory buffer built into the ECU, and may store various timer values and sensing data according to the present embodiment.

The direct memory access (DMA) module 1170 may be a module for managing data in a storage. When a reception interrupt of a sensor signal is generated by the interrupt router module 1160, the DMA module 1170 may control the function of storing a system timer value at the time of receiving the sensor signal and sensing data (i.e., SENT frame) included in the sensor signal received from the sensor in a specific location in a memory buffer.

In addition, the central processing unit (CPU) 1130 or a SENT module may access the data stored in the memory buffer through the driver function of the DMA module 1170.

The SENT module may be a module for managing transmission, reception and storage of data within the first ECU 1100.

By using the DMA module 1170, the central processing unit (CPU) 1130 or the SENT module may extract the system timer values stored in the ECU storage unit 1160, and detect a short-circuit between sub-systems using the extracted system timer values.

For example, if the transmission period of the sensor trigger signal is 200 us and the execution period of the specific periodic function is 1 ms, the central processing unit (CPU) 1130 or the SENT module may extract a number of system timer values stored in the ECU storage 1160 prior to the execution of a specific periodic function. The central processing unit 1130 or the SENT module may calculate a difference value between the extracted system timer values and compares the difference value with a preset threshold value.

The central processing unit 1130 or the SENT module may determine that a short-circuit between the first sub-system 1000 and the second sub-system 2000 has occurred if at least one of the difference values between the system timer values is different from the threshold value.

Specifically, the central processing unit 1130 or the SENT module may determine that a short-circuit between the first sensor signal line 1300 and another sensor signal line included in another sub-system has occurred, and thus the received sensor signal has an error or is abnormal.

In the case that the first ECU 1100 detects the occurrence of a short-circuit with at least one of other sub-systems, if the vehicle is controlled using a sensor signal in which the abnormality has occurred, the functional stability of the vehicle may not be guaranteed.

Accordingly, in this case, the entire distribution system may be shut down. Alternatively, if the first ECU 1100 detects occurrence of a short-circuit with another sub-system, a specific warning signal may be provided to a driver or a vehicle operator.

Meanwhile, the first ECU 1100 may perform an initialization function for initial configuration setting when the first sensor signal is received from the first sensor 1200 through the first signal line 1300.

The initialization parameters used for such initial configuration settings may include at least one of 1) a first system timer value or storage location thereof (e.g., the register address of the system timer) when receiving the first sensor signal, 2) setting information of a transmission period of a sensor trigger signal, 3) processing priority information of an interrupt router (IR) module, 4) storage target information to be stored in an ECU storage (ECU memory) through a direct memory access (DMA) module, and 5) storage location information in the ECU memory for storing the storage target information.

These initialization parameters may be defined or referred as a set value required to perform an operation required for short-circuit detection according to the present embodiment.

The first system timer value at the time of receiving the first sensor signal or its storage location may be a parameter set to acquire a system timer value each time the sensor signal reception event or operation is completed.

The setting information of the transmission period of the sensor trigger signal may be a parameter for setting the transmission period value of the sensor trigger signal. The transmission period of the sensor trigger signal may be smaller than the execution period of the periodic function for performing the function for vehicle control. As an example, the execution period of the periodic function may be 1 ms, and the transmission period of the sensor trigger signal or the transmission/reception period of the sensor signal may be one of 125 us, 200 us, and 250 us.

In addition, in one embodiment, the execution period of the periodic function may be an integer multiple of the transmission/reception period of the sensor signal of the first sensor.

The shorter the transmission period of the sensor trigger signal or the shorter the transmission/reception period of the sensor signal, the more frequent the sensor signal reception is, so that the sensor signal can be acquired quickly.

Among the initialization parameters, the processing priority information of the interrupt router module may be a parameter for determining the order for the interrupt router module 1150 to process the interrupt for receiving the sensor signal according to the present embodiment.

In general, the interrupt router module 1150 processes a number of interrupt generation requests from the CPU 1130 or the like.

The sensor signal receiving interrupt for detecting a short-circuit between sub-systems according to the present embodiment may have relatively low importance or priority compared to other interrupts. Therefore, in an embodiment, the processing priority of the interrupt router module may be set to a low priority. Accordingly, it is possible to prevent the degradation of the overall operation of the distribution system by performing another interrupt first.

Among the initialization parameters, the storage target information to be stored in the ECU memory may include a sensor register value for transmitting a sensor signal, storage location information of an ECU storage 1160 to store data, a system timer value when receiving a sensor signal, and sensing data (e.g. SENT Frame, etc.) included in the sensor signal.

An example of a specific configuration of initialization and short-circuit detection according to the present embodiment will be described as follows.

First, in the initialization process, a register address of a system timer in which a system timer value to be read when a sensor signal reception event occurs may be set as a source address. In addition, a specific address of the ECU storage 1160 for storing the extracted system timer value may be set as a destination address. In addition, in the initialization process, the transmission period of the sensor trigger signal may also be set.

Thereafter, if the periodic function is executed, the interrupt router module 1150 may transmit the sensor trigger signal to the first sensor 1200 at every predetermined transmission period of the sensor trigger signal.

If the sensor signal is received from the first sensor 1200, the SENT module in the first ECU 1100 may notify the interrupt router module 1150 of the reception completion, and the interrupt router module 1150 may notify the DMA module 1170 of the reception completion event.

The DMA module 1170 confirming the reception completion event may read or extract a system timer value in the system timer register, which is the source address, without intervention of the CPU 1130 of the first ECU 1100, and may stores in a specific location (i.e., a specific buffer) of the ECU storage 1160, which is the destination address. Accordingly, it is possible to reduce the computational load of the CPU 1130 of the first ECU 1100.

Through this process, the system timer value may be stored in the ECU memory for each transmission period of the sensor trigger signal. As a result, when the periodic function is executed once, a plurality of system timer values are respectively stored in different memory buffers (e.g. ECU memory).

Meanwhile, in order to perform the short-circuit detection function according to the present embodiment, the DMA module 1170 may extract a plurality of system timer values stored in the ECU memory 1160 without the intervention of the CPU 1130 and transmits the system timer values to the CPU 1130.

The CPU 1130 may determine a difference value between two temporally consecutive system timer values and compares the difference value with a threshold value to detect a short-circuit between sub-systems.

As described above, in the present embodiment, the system timer value is stored each time a sensor signal is received by further using the interrupt router module and direct memory access (DMA) module included in the ECU of the sub-system, and the difference value is compared with a threshold value, thereby detecting a short-circuit between sub-systems.

In the above, the first sub-system 1000 and the first ECU 1100 included in the distribution system have been described, but the second sub-system 2000 and the second ECU 2100 included therein may also perform the aforementioned initialization function and short-circuit detection function.

That is, the distribution system according to the present embodiment may include two or more sub-systems performing the same function, and each sub-system and the ECU included therein may perform the short-circuit detection function according to the present disclosure.

Meanwhile, the first ECU 1100 as a short-circuit detection device may be configured to further perform, in addition to the first short-circuit detection performed based on the interval of the system timer value, a second short-circuit detection by checking a protocol error between the first sensor 1200 and the first ECU 1100, a third short-circuit detection by checking a reception error in which the first ECU 1100 cannot receive a sensor signal from the first sensor 1200, and a fourth short-circuit detection through analysis of reception signal pattern.

In the second short-circuit detection, a short-circuit between sub-systems can be detected by detecting an error in the SENT protocol, which is a protocol between the first sensor 1200 and the first ECU 1100. The errors in the SENT protocol may include an error in the number of nibbles in the frame, an out of range error in the nibble value, an error in length exceeding the synchronization/calibration pulse, and CRC checksum error.

In the third short-circuit detection, a reception missing error in which a signal to be received from the ECU does not exist due to the non-transmission of the sensor signal by the sensor can be detected. In addition, if such a reception missing error occurs, there may be determined that a short-circuit has occurred between the sub-systems.

In the fourth short-circuit detection, an occurrence of a short-circuit between sub-systems can be detected by analyzing the pulse pattern of the sensor signal received by each ECU.

Specifically, in the fourth short-circuit detection, a pattern of the first sensor signal of the first sensor 1200 of the first sub-system 1100, a pattern of the second sensor signal of the second sensor 2200 of the second sub-system 2100, and an overlapping signal pattern capable of being generated by the overlapping of the first and second sensor signals may be pre-stored.

In this case, each ECU of a respective sub-system may compare the pattern of a sensor signal received from a sensor with the pre-stored pattern, and if there is a matching overlapping signal pattern or it is different from the pre-stored first and second sensor signal pattern, there may be determined that a short-circuit has occurred between the sub-systems.

As described above, according to the present embodiment, the first ECU 1100 as a short-circuit detection device may further perform the second to fourth short-circuit detection methods in addition to the first short-circuit detection based on the interval of the system timer value, so that it is possible to detect more precisely the short-circuit between sub-systems.

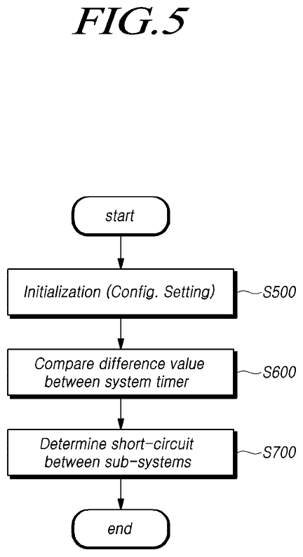

FIG. 5 is a flowchart of a method for detecting a short-circuit in a distribution system for a vehicle according to an embodiment of the present disclosure.

The short-circuit detection method according to the present embodiment may be performed in a distribution system including a first sub-system for performing a function related to vehicle control and a second sub-system for performing the function in conjunction with the first sub-system.

Specifically, the short-circuit detection method according to the present embodiment may be performed by the first sub-system and/or the second sub-system, and may include an initialization step of performing an initial configuration setting when an initial sensor signal is received from a first sensor through a first signal line connected to the first sensor (S500).

In addition, the short-circuit detection method according to the present embodiment may include, when executing a specific periodic function, a comparison step of comparing a difference value between a current system timer value when receiving a current sensor signal from the first sensor and a previous system timer value when receiving a previous sensor signal from the first sensor with a threshold value (S600).

In addition, the short-circuit detection method according to the present embodiment may include a step of determining a short-circuit of a signal line between the first sub-system and the second sub-system based on the comparison result of the threshold value and the difference value between the current system timer value and the previous system timer value (S700).

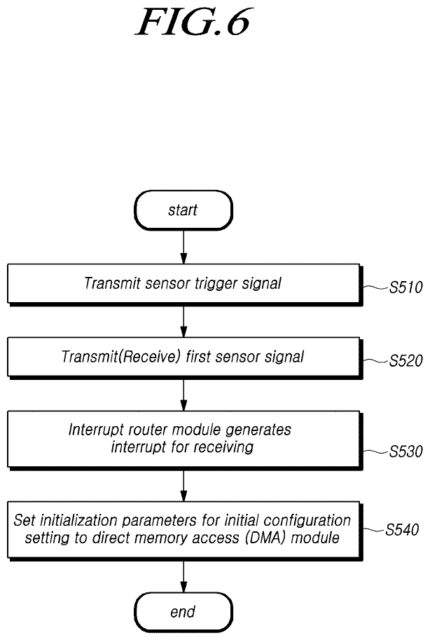

FIG. 6 is a flowchart of an initialization process included in a short-circuit detection method according to an embodiment of the present disclosure.

In the initialization step (S500 of FIG. 5), the first ECU included in the first sub-system may transmit a sensor trigger signal for initialization to the first sensor (S510).

The first sensor may generate a first sensor signal or an initial sensor signal in response to reception of the sensor trigger signal for initialization and transmit the first sensor signal to the first ECU (S520).

A first ECU may generate a reception interrupt by using an interrupt router module (S530).

The first ECU may utilize a direct memory access (DMA) module to perform the initial configuration setting to set various parameters required to perform the short-circuit detection function according to the present embodiment (S540).

The initialization parameters used for the initial configuration setting may include at least one of 1) the first system timer value when the first sensor signal is received, 2) setting information of the transmission period of the sensor trigger signal, 3) the processing priority information of the interrupt router module, 4) storage target information to be stored in the ECU memory through a direct memory access module, and 5) storage location information in the ECU memory for storing the storage target information.

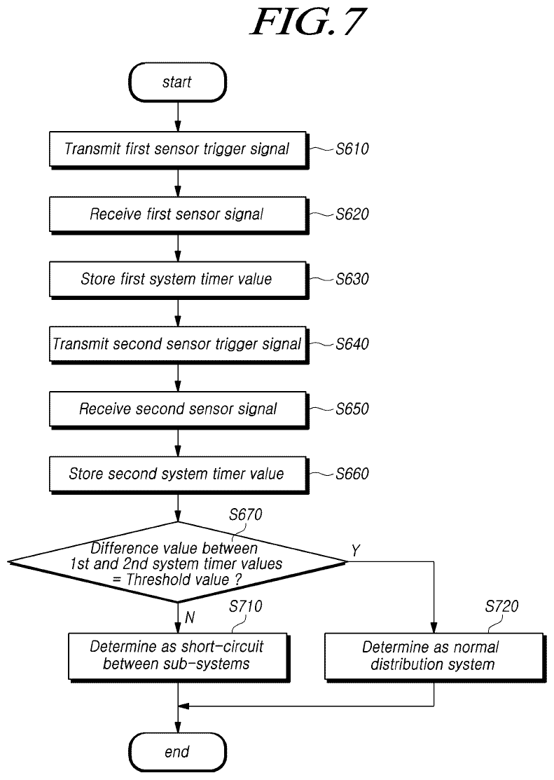

After the initialization is completed, as will be described with reference to FIG. 7, the first ECU may perform a short-circuit detection function between sub-systems using the interval of the system timer value.

FIG. 7 is a flowchart for detecting a short-circuit included in a method for detecting a short-circuit according to an exemplary embodiment of the present disclosure.

The exemplary embodiment of the short-circuit detection method of FIG. 7 may utilize an interval of system timer values.

Specifically, in the method for detecting a short-circuit when executing a periodic function, the first ECU of the first sub-system may transmit a first sensor trigger signal to the first sensor (S610).

The first sensor may generate a first sensor signal including first sensing data in response to the reception of the first sensor trigger signal and transmit the first sensor signal to the first ECU through the first sensor signal line (S620).

The first ECU may receive the first sensor signal and store a first system timer value at the time T1 when receiving the first sensor signal according to the initial configuration setting in the initialization in the ECU storage (S630).

When a transmission period Pt of the sensor trigger signal has elapsed, the first ECU may transmit a second sensor trigger signal to the first sensor (S640).

The first sensor may generate a second sensor signal including second sensing data in response to the reception of the second sensor trigger signal and transmit the second sensor signal to the first ECU through the first sensor signal line (S650).

The first ECU may receive the second sensor signal and store a second system timer value at the time T2 when receiving the second sensor signal in the ECU storage (S660).

In this embodiment, the second system timer value may be the current system timer value, and the first system timer value may be the previous system timer value.

The first ECU may determine a difference value Td between the second system timer value and the first system timer value, and compare the difference value with a preset threshold value or range Tth (S670).

In this case, the threshold value Tth may be the same value as the transmission period Pt of the sensor trigger signal or the transmission/reception period of the sensor signal, or may be set a value obtained by adding or subtracting a certain margin to the transmission period Pt of the sensor trigger signal or the transmission/reception period of the sensor signal.

Depending on the comparison result, if the difference value Td is different from the threshold value (or out of the threshold range) Tth, the first sub-system may determine that a short-circuit with another sub-system had occurred (S710).

Specifically, the first ECU may determine that the first sensor signal line between the first ECU and the first sensor inside the first sub-system is short-circuited with the second sensor signal line inside the second sub-system which is another sub-system.

In addition, if the difference value Td is substantially equal to the threshold value (or within the threshold range) Tth, the first ECU may determine that the distribution system is operating normally, that is, that a short-circuit between sub-systems does not occur (S720).

In the above description, it has been described that two system timer values are stored and the difference value is compared with a threshold value, however, the present disclosure is not limited thereto. As another example, after storing N system timer values during one execution of the periodic function, N−1 difference values may be determined and compared with a threshold value.

Although not shown, if it is determined in step S710 that a short-circuit between sub-systems has occurred, the distribution system may output a specific warning signal or stop the operation of the distribution system.

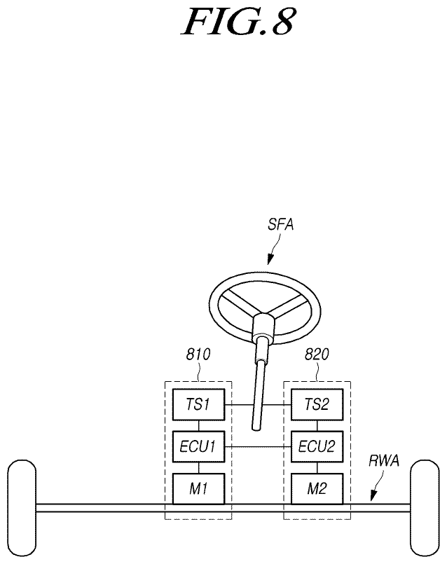

FIG. 8 is a block diagram of a steer-by-wire steering system including a distribution system which is capable of detecting short-circuit according to an exemplary embodiment of the present disclosure.

A first function related to vehicle control performed by the distribution system according to an embodiment of the present disclosure may include one or more various control functions included in a driver assistance system (DAS), an automatic steering system and an automatic braking system necessary for autonomous or semi-autonomous driving.

Among these functions, compared to the DAS function, an automatic steering system, an automatic braking system, and the like necessary for autonomous or semi-autonomous driving are more important for functional safety of a vehicle. Accordingly, the distribution system according to the present disclosure may perform the first function for automatic steering and/or automatic braking necessary for autonomous or semi-autonomous driving.

FIG. 8 illustrates overall configuration of a steer-by-wire (SBW) steering system as an automatic steering system to which the distribution system according to one or more embodiments of the present disclosure is applied.

The steer-by-wire (SBW) steering system of a vehicle may refer to a steering system for steering a vehicle using an electric motor such as a steering motor, and may remove a mechanical connection device such as a steering column or a universal joint or a pinion shaft between a steering wheel and a wheel of the vehicle.

The SBW steering system may generally include an upper stage device, a lower stage device, and a control device for controlling the same. The upper stage device may include a torque sensor connected to a steering wheel to detect a steering torque applied to the steering wheel, and a reaction force motor as a motor device for providing a reaction torque to the steering wheel according to steering through the lower rack bar. This upper stage device may be referred as a steering feedback actuator (SFA).

In addition, the lower stage device may generate a steering assistance torque signal proportional to the steering torque applied to the steering wheel, and may control a steering drive motor or a steering drive actuator which drives a pinion gear or a gear (e.g. ball nut) mechanism for moving a rack bar connected to a tie rod of left and right of the wheel of the vehicle by using a steering assistance torque signal. Such a lower stage device may be referred as a road wheel actuator (RWA).

During the autonomous driving, a controller of the SBW steering system may automatically control the steering drive motor to provide an automatic steering function so that the vehicle can travel in a desired path.

The automatic steering for autonomous driving may be an important function for vehicle functional safety, and therefore, the distribution system having the short-circuit detection technology according to the present embodiment may be needed.

Referring to FIG. 8, the SBW steering system to which one or more embodiments of the present disclosure is applied may include a steering feedback actuator (SFA) including torque sensors TS1 and TS2 operatively connected to a steering wheel as an upper stage device, and a road wheel actuator (RWA) including two redundant steering drive motors M1 and M2.

In addition, a first ECU ECU1 and a second ECU ECU2 may be provided for controlling each of the two redundant steering drive motors.

Specifically, the first ECU ECU1, the first torque sensor TS1 and the first steering drive motor M1 may constitute a first sub-system 810, and the second ECU ECU2, the second torque sensor TS2 and the second steering drive motor M2 may constitute a second sub-system 820.

The first and second sub-systems 810 and 820 may perform the same or similar automatic steering function.

In this case, the first ECU ECU1 or the second ECU ECU2 may be configured like the first ECU 1100 as shown in FIG. 4, thereby performing a function of detecting short-circuit between sub-systems using the interval of system timer values according to the present embodiment.

That is, if a specific periodic function is executed for automatic steering for autonomous driving, the first ECU ECU1 or the second ECU ECU2 may detect the occurrence of a short-circuit with another sub-system by comparing a difference value between a current system timer value when receiving a current sensor signal and a previous system timer value when receiving a previous sensor signal a threshold value.

In the case that a short-circuit between sub-systems is detected, it is possible to satisfy the functional stability requirement of the vehicle by stopping the operation of the SBW distribution system for automatic steering or warning.

The distribution system having the short-circuit detection function according to the present embodiment may be applied to a brake-by-wire (BBW) type automatic braking system in addition to the steering system above-described.

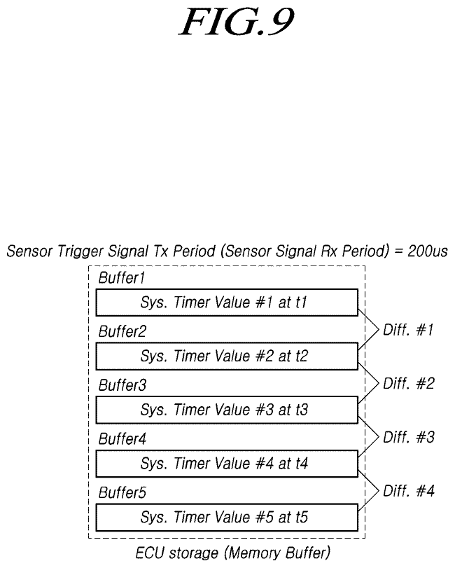

FIG. 9 illustrates an example of information stored in an ECU storage in a device for detecting short-circuit according to an embodiment of the present disclosure.

In the distribution system according to an embodiment of the present disclosure, it is assumed that the execution period of the periodic function is 1 ms and the transmission period Pt of the sensor trigger signal is 200 us for illustration purpose.

First, the ECU included in the distribution system may perform initialization process.

In the initialization process, the first to fifth memory buffers Buffers 1˜5 may be set as specific addresses of the ECU storage in which the extracted system timer values are to be stored.

Thereafter, when a periodic function having a period of 1 ms is executed, the interrupt router module may transmit a sensor trigger signal to the first sensor every 200 us, which is a transmission period of the sensor trigger signal. That is, transmission of a sensor trigger signal and reception of a sensor signal are performed five times during the execution of one periodic function. That is, transmission of the sensor trigger signal and reception of the sensor signal are performed every time interval of t1 to t5.

If the first sensor signal to the fifth sensor signal are received from the first sensor, each time a sensor signal is received, the direct memory access (DMA) module in the ECU reads a system timer value in a system timer register which is a source address, and stores to the first to fifth memory buffers Buffers 1˜5, respectively.

That is, as shown in FIG. 9, during one execution of the periodic function, the first to fifth system timer values are stored in the first to fifth memory buffers Buffers 1˜5, respectively.

Accordingly, the system timer value is extracted for each transmission period of the sensor trigger signal of the 200 us period, and if the periodic function is executed once, a total of five system timer values are stored in different memory buffers (ECU memory), respectively.

Thereafter, the CPU of the ECU may determine a difference value between two temporally consecutive system timer values, compare the difference value with a threshold value or range, and detect a short-circuit between sub-systems.

In the exemplary embodiment of FIG. 9, the CPU of the ECU may determine a first difference value Diff. #1 between a first system timer value stored in a first memory buffer Buffer 1 and a second system timer value stored in a second memory buffer Buffer 2. Similarly, the CPU of the ECU may determine a second difference value Diff. #2 between the second system timer value stored in the second memory buffer Buffer 2 and a third system timer value stored in a third memory buffer Buffer 3, a third difference value Diff. #3 between the third system timer value stored in the third memory buffer Buffer 3 and a fourth system timer value stored in the fourth memory buffer Buffer 4, a fourth difference value Diff. #4 between the fourth system timer value stored in the fourth memory buffer Buffer #4 and a fifth system timer value stored in a fifth memory buffer Buffer #5, respectively.

Thereafter, the CPU may compare at least one of the first to fourth difference values Diff. #1 to 4 with a threshold value or range (e.g. the transmission period Pt of the sensor trigger signal). In addition, if one or more of the first to fourth difference values Diff. #1 to 4 are different from the threshold value or out of the threshold range, the CPU may determine that a short-circuit has occurred between the two sub-systems.

Meanwhile, in the above description, the distribution system has been described as a redundant configuration including the first and second sub-systems. However, the present disclosure is not limited thereto, and the present disclosure is similarly applicable to an asynchronous multiplexed distributed system including three or more sub-systems performing the same function.

According to certain embodiments of the present disclosure, it is possible to detect a short-circuit of a signal (line) between sub-systems in a distribution system including two or more sub-systems which are capable of performing the same function.

Specifically, in a distribution or redundancy system including a plurality of sub-systems, a short-circuit between a first sensor signal line between a first ECU and a first sensor included in a first sub-system and a second sensor signal line between a second ECU and a second sensor included in a second sub-system can be detected.

Accordingly, by detecting a short-circuit between a plurality of sub-systems in a distribution system for a vehicle, a stable operation of the distribution system can be secured, and a functional safety requirement required for a vehicle can be satisfied.

In this specification, even if all the components constituting the embodiment are described as being combined or operating in combination, the present disclosure is not necessarily limited to this embodiment. That is, within the scope of the object of the present disclosure, all the components may operate by selectively combining one or more. In addition, all of the components may be implemented as one independent hardware, but there may be implemented as a computer program having a program module performing some or all of the functions of the combined hardware in one or a plurality of hardware by selectively combining a part or all of each component. Codes and code segments constituting a computer program can be easily deduced by those skilled in the art of the present disclosure. Such a computer program may be stored in a computer readable storage medium, read and executed by the computer, thereby implementing the embodiment of the present disclosure. The storage medium of the computer program may include a magnetic recording medium, an optical recording medium, a carrier wave medium, and the like.

In addition, terms such as “include”, “compose”, “comprise” or “have” described above should be interpreted as not excluding, but may further include other components since it means that the corresponding component can be embedded, unless otherwise stated. All terms, including technical and scientific terms, have the same meaning as commonly understood by one of ordinary skill in the art to which the present disclosure belongs, unless otherwise defined. Terms commonly used, such as those defined in the dictionary, should be interpreted as being consistent with the meaning in the context of the related art, and should be not interpreted in an ideal or excessively formal meaning unless explicitly defined in the present disclosure.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims. The scope of protection of the present disclosure should be construed based on the following claims, and all technical ideas within the scope of equivalents thereof should be construed as being included within the scope of the present disclosure.

What is claimed is:

1. A device for detecting a short-circuit of a sub-system in a distribution system including a plurality of sub-systems performing vehicle control, the device comprising:
a sensor;
an electronic control unit (ECU) electrically connected to the sensor; and
a signal line connecting the sensor and the ECU,
wherein the ECU is configured to:
perform initialization for initial configuration setting when receiving a sensor signal through the signal line, and when executing a periodic function performed periodically, detect a short-circuit with another sub-system included in the distribution system, by using a difference value between a current system timer value when receiving a current sensor signal and a previous system timer value when receiving a previous sensor signal.

2. The device of claim 1, wherein the ECU comprises:
a sensor transceiver configured to transmit and receive one or more signals including the sensor signal to and from the sensor;
a system timer configured to generate the current system timer value and the previous system timer value;
a central processing unit configured to perform the initialization and detect the short-circuit;
an ECU transceiver configured to transmit and receive one or more signals to and from another ECU of the another sub-system;
an interrupt router module configured to generate an interrupt for receiving the sensor signal; and
an ECU storage configured to store the current system timer value and the previous system timer value.

3. The device of claim 2, wherein the ECU further comprises a direct memory access (DMA) module,
wherein the interrupt router module is configured to transmit a sensor trigger signal to the sensor,
the sensor is configured to transmit the sensor signal including sensing data to the ECU in response to receiving the sensor trigger signal, and
the DMA module is configured to store the sensing data, the current system timer value, and the previous system timer value in the ECU storage.

4. The device of claim 3, wherein initialization parameters used for the initial configuration settings comprise at least one of a system timer value or storage location of the system timer value when receiving the sensor signal, setting information of a transmission period of the sensor trigger signal, processing priority information of the interrupt router module, storage target information to be stored in the ECU storage through the DMA module, and storage location information in the ECU storage for storing the storage target information.

5. The device of claim 1, wherein the ECU is configured to compare the difference value between the current system timer value and the previous system timer value with a threshold value or range, and determine that the short-circuit with the another sub-system has occurred if the difference value between the current system timer value and the previous system timer value is different from the threshold value or out of the threshold range.

6. The device of claim 5, wherein the threshold value is a transmission and/or reception period of the sensor signal of the sensor.

7. The device of claim 6, wherein an execution period of the periodic function is an integer multiple of the transmission and/or reception period of the sensor signal of the sensor.

8. The device of claim 1, wherein the distribution system is for a steer-by-wire steering system for automatic steering control during autonomous driving, and the sensor includes at least one steering torque sensor or a motor position sensor of a steering motor.

9. The device of claim 1, wherein the ECU is configured to determine that the short-circuit with the another sub-system has occurred if a protocol error between the sensor and the ECU or a reception error in which the ECU is unable to receive the sensor signal from the sensor occurs.

10. A distribution system comprising:
a first sub-system including a first ECU, a first sensor, and a first sensor signal line connecting the first ECU and the first sensor, the first sub-system configured to perform a function related to vehicle control; and
a second sub-system including a second ECU, a second sensor, and a second sensor signal line connecting the second ECU and the second sensor, the second sub-system configured to perform the function related to the vehicle control in conjunction with the first sub-system,
wherein the first ECU is configured to, when executing a periodic function performed periodically, calculate a difference value between a current system timer value when receiving a current sensor signal through the first sensor signal line and a previous system timer value when receiving a previous sensor signal through the first sensor signal line, and detect a short-circuit between the first sensor signal line and the second sensor signal line based on the difference value between the current system timer value and the previous system time value.

11. The distribution system of claim 10, wherein the first ECU is configured to perform initialization for initial configuration setting when receiving a first sensor signal through the first sensor signal line.

12. The distribution system of claim 11, wherein the first ECU comprises:
a sensor transceiver configured to transmit and receive one or more signals the first sensor signal to and from the first sensor;
a system timer configured to generate the current system timer value and the previous system timer value; and
a central processing unit configured to perform the initialization and detect the short-circuit.

13. The distribution system of claim 12, wherein the first ECU further comprises:
an interrupt router module configured to generate an interrupt for receiving the current sensor signal and the previous sensor signal; and
an ECU storage configured to store the current system timer value and the previous system timer value.

14. The distribution system of claim 10, wherein the first ECU is configured to compare the difference value between the current system timer value and the previous system timer value with a threshold value or range, and determine that the short-circuit has occurred between the first sensor signal line and the second sensor signal line if the difference value is different from the threshold value or out of the threshold range.

15. The distribution system of claim 14, wherein the threshold value is a transmission and/or reception period of the first sensor signal of the first sensor.

16. The distribution system of claim 10, wherein the function related to the vehicle control includes a control function of a steer-by-wire steering system for autonomous driving, and the first sensor and the second sensor include at least one steering torque sensor and/or a motor position sensor of a steering motor.

17. A method for detecting short-circuit between sub-systems in a distribution system including a first sub-system for performing a function related to vehicle control and a second sub-system for performing the function related to the vehicle control in conjunction with the first sub-system, the method comprising:
performing, by the first sub-system, initialization for initial configuration setting when a first sensor signal is received from a first sensor of the first sub-system through a first sensor signal line connected to the first sensor;
when executing a periodic function periodically performed, calculating, by the first sub-system, a difference value between a current system timer value when receiving a current sensor signal from the first sensor and a previous system timer value when receiving a previous sensor signal from the first sensor; and
performing, by the first sub-system, a determination of a short-circuit between the first sensor signal line of the first sub-system and a second sensor signal line of the second sub-system.

18. The method of claim 17, wherein the performing of the determination of the short-circuit comprises comparing the difference value between the current system timer value and the previous system timer value with a threshold value or range, and determining that the short-circuit between the first sensor signal line of the first sub-system and the second sensor signal line of the second sub-system has occurred if the difference value between the current system timer value and the previous system timer value is different from the threshold value or out of the threshold range.

19. The method of claim 18, wherein the threshold value is a transmission and/or reception period of the first sensor signal of the first sensor.

20. The method of claim 17, wherein the function related to the vehicle control includes a control function of a steer-by-wire steering system for autonomous driving, and the first sensor included in the first sub-system and a second sensor included in the second sub-system include at least one steering torque sensor and/or a motor position sensor of a steering motor.
